(19) United States
(12) Patent Application Publication
(10) Pub. No.: US 2024/0179900 A1
(43) Pub. Date: May 30, 2024

(54) Non-volatile Memory Cell

(71) Applicant: AMIC Technology Corporation, Hsin-Chu City (TW)

(72) Inventors: Hsiao-Hua Lu, Hsinchu County (TW); Yung-Tien Peng, Hsinchu City (TW); Chun-Hao Huang, Kaohsiung City (TW)

(73) Assignee: AMIC Technology Corporation, Hsin-Chu City (TW)

(21) Appl. No.: 18/086,668

(22) Filed: Dec. 22, 2022

(30) Foreign Application Priority Data
Nov. 29, 2022 (TW) 111145726

(51) Int. Cl. H10B 41/70; H10B 41/10; H10B 41/35

(52) U.S. Cl. CPC H01L 27/1156; H01L 27/11519; H01L 27/11524

(57) ABSTRACT

A non-volatile memory cell includes a tunneling part; a coupling transistor, including a coupling gate part, a first conductive region and a second conductive region, wherein the coupling gate part is coupled to the tunneling part and disposed in the first conductive region; a read transistor with a read gate part coupled to the tunneling part for forming an electron tunneling ejection path in an erase mode, and forming an electron tunneling injection path in a program mode; and a select transistor, connected in series with the read transistor, for forming a read path with the read transistor in a read mode.

### BACKGROUND OF THE INVENTION

### 1. Field of the Invention

The present invention relates to a non-volatile memory cell, and more particularly, to a non-volatile memory cell with a simplified structure.

### 2. Description of the Prior Art

Non-volatile memory is a storage device which is capable of storing data without power supply. Common non-volatile memories include magnetic memory devices, CD-ROM, flash memory, etc. In general, the non-volatile memory is usually fabricated by a logic based complementary metal oxide semiconductor (CMOS) process. Each non-volatile memory may operate in a read mode, a program mode and an erase mode.

For example, please refer to FIG. 1A and FIG. 1B. FIG. 1A is a schematic diagram of a circuit layout of a non-volatile memory cell 10 according to U.S. Pat. No. 8,625,350B2. FIG. 1B is a schematic circuit diagram of the non-volatile memory cell 10. The non-volatile memory cell 10 includes a coupling transistor 100, a read transistor 110, an erase transistor 120, a word transistor 130 and a bit transistor 140. When the non-volatile memory cell 10 is operated in the erase mode, the electron tunneling effect occurs in the erase transistor 120. Electrons are tunneling ejected from a floating gate FG1 of the read transistor 110; when the non-volatile memory cell 10 is operated in the program mode, the electrons are tunneling injected to the floating gate FG1 of the read transistor 110; and when the non-volatile memory cell 10 is operated in the read mode, the logical status of the non-volatile memory cell 10 is determined according to a read current IR1 flowing through the read transistor 110. It should be noted that, as shown in FIG. 1A, five transistors and devices included in the non-volatile memory cell 10 need to be arranged on at least two independent N-wells and one P-well. Therefore, fabricating the non-volatile memory cell 10 requires complicated semiconductor process steps.

Therefore, how to provide the non-volatile memory cell that uses fewer transistors and devices, and can realize basic operations (the erase mode, the program mode and the read mode) has become one of the goals of the industry.

### SUMMARY OF THE INVENTION

Therefore, the purpose of the present invention is to provide a non-volatile memory cell with a simplified structure to improve the drawback of the prior art.

The embodiment of the present invention discloses a non-volatile memory cell including a tunneling part; a coupling transistor, comprising a coupling gate part, a first conductive region and a second conductive region, wherein the coupling gate part is coupled to the tunneling part, and disposed in the first conductive region; a read transistor with a read gate part coupled to the tunneling part, for forming an electron tunneling ejection path in an erase mode, and forming an electron tunneling injection path in a program mode; and a select transistor, connected in series with the read transistor, for forming a read path with the read transistor in a read mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a top view of a circuit layout of a non-volatile memory cell according to the prior art.

FIG. 1B is a schematic circuit diagram of the non-volatile memory cell shown in FIG. 1A.

FIG. 2A is a schematic circuit diagram of a non-volatile memory cell according to an embodiment of the present invention.

FIG. 2B is a top view of a circuit layout of the non-volatile memory cell shown in FIG. 2A.

FIG. 3 is a top view of a circuit layout of a non-volatile memory cell according to another embodiment of the present invention.

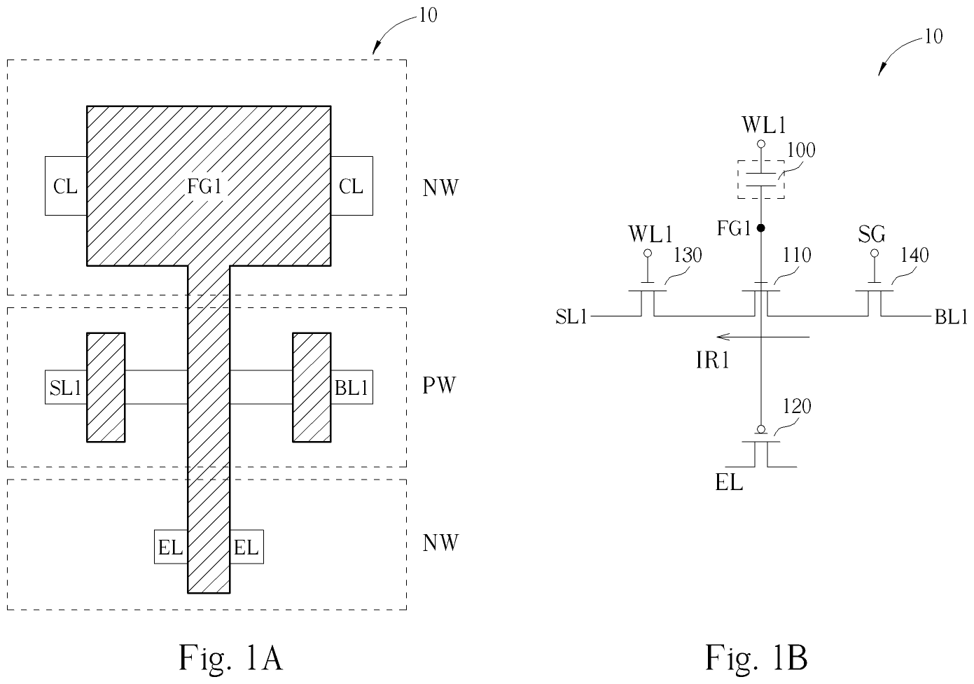

### DETAILED DESCRIPTION

The non-volatile memory cell in the present invention is fabricated by a logic-based complementary metal oxide semiconductor (CMOS) process. The logic-based CMOS process is known in the art. In short, in a fabrication perspective, the logic-based CMOS process implants an active region in an electron well, and forms an insulation layer and a conductive layer in the electron well above the active region. In a circuit layout perspective, the active region is under the insulation layer and the conductive layer, and the electron well is disposed under the active region. Therefore, in the following description and in the claims, “over” and “under” represent relative positions of different layers in circuit layout. For example, “the electron well is disposed under the active region” represents the active region is implanted in the electron well, and “the insulation layer and the conductive layer are disposed over the active region” or “the active region is disposed under the insulation layer and the conductive layer” represents that the insulation layer and the conductive layer are formed in the electron well above the active region.

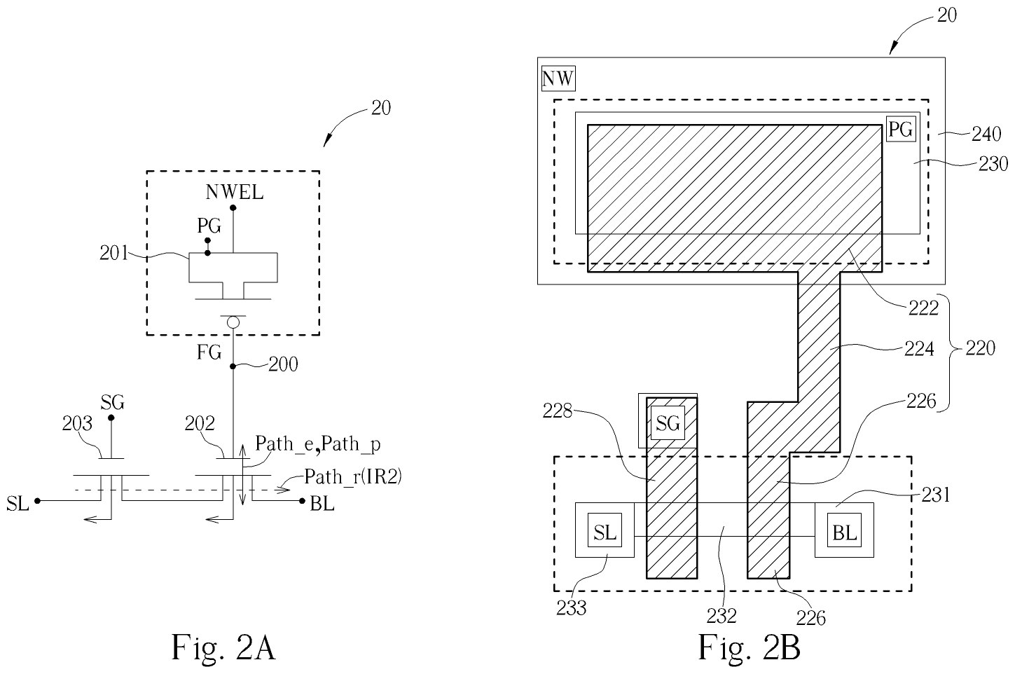

Please refer to FIG. 2A and FIG. 2B. FIG. 2A and FIG. 2B are a schematic circuit diagram and a top view of a circuit layout of a non-volatile memory cell 20 respectively according to an embodiment of the present invention. As shown in FIG. 2A, the non-volatile memory cell 20 includes a charge storage node 200, a coupling transistor 201, a read transistor 202 and a select transistor 203. The coupling transistor 201 and the read transistor 202 are both coupled to the charge storage node 200, and the read transistor 202 is connected in series with the select transistor 203 to form a read path Path_r. The charge storage node 200 is used to store charges to memorize a logical status of the non-volatile memory cell 20. In detail, the voltage of the charge storage node 200 changes with electron ejection and electron injection. When the non-volatile memory cell 20 performs an erase operation, an electron tunneling ejection path Path_e is formed through the read transistor 202, and electrons are ejected from the charge storage node 200; and when the non-volatile memory cell 20 performs a program operation, an electron tunneling injection path Path_p is formed through the read transistor 202, and electrons are injected to the charge storage node 200. It should be noted that the electron tunneling ejection path Path_e is the same path as the electron tunneling injection path Path_p, but the electrons move in opposite directions. In this way, when the non-volatile memory cell 20 performs the read operation, the voltage of the charge storage node 200 is corresponding to a current value of a read current IR2 on the read path path_r. Therefore, the logical status of the charge storage node 200 may be determined and read by sensing the current value of the read current IR2 flowing through the read transistor 202.

Specifically, the non-volatile memory cell 20 is fabricated by a logic-based CMOS process, and a circuit layout of the non-volatile memory cell 20 is illustrated in FIG. 2B. As shown in FIG. 2B, the non-volatile memory cell 20 includes a floating gate part 220, a select gate part 228, active region 230-233 and an electronic well 240. The floating gate part 220 and the select gate part 228 are formed by a conductive layer and an insulation layer. The conductive layer may be made of conductive material such as metal or poly-silicon, and the insulation layer may be made of insulation material such as silicon dioxide. The active region 230 may be a P+ active region, the active region 231-233 may be an N+ active region, and the electronic well 240 may be an N well. The floating gate part 220 corresponds to the charge storage node 200 in FIG. 2A, and may be divided into a coupling gate part 222, a tunneling part 224 and a read gate part 226. The coupling gate part 222 is disposed on the active region 230 to form the coupling transistor 201 in FIG. 2A. The read gate part 226 and the active regions 231, 232 form the read transistor 202 in FIG. 2A, and the select gate part 228 and the active regions 232, 233 form the select transistor 203 in FIG. 2A. The active region 230 may surround the coupling gate part 222 to couple the coupling gate part 222 to a specific voltage. In addition, the active region 230 must be implanted on the electronic well 240.

The non-volatile memory cell 20 may perform a program, erase or read operation through proper bias voltages. Specifically, a first conductive region formed by the active region 230 is used to receive a program voltage PG. A second conductive region formed by the electronic well 240 is used to receive an electronic well voltage NW. The active region 231 is used to receive a bit line voltage BL. The active region 233 is used to receive a source line voltage SL. The select gate part 228 is used to receive a read word line voltage RWL. The details about program, erase and read operations are as follows:

In the erase mode, the read word line voltage RWL is a low voltage, so that the select transistor 203 is turned off. The program voltage PG is a negative voltage, the electronic well voltage NW is the low voltage, and the bit line voltage BL and the source line voltage SL are both a medium voltage. And a voltage difference between the medium voltage and the negative voltage must be sufficient to induce the tunneling effect. Therefore, the voltage difference between the active region 231 and the tunneling part 224 is sufficient to cause the read transistor 202 to induce the electrons tunneling ejecting for the erase operation. In an embodiment, the negative voltage is −6V, the medium voltage is 5V, and the low voltage is 0V. In this way, the voltage difference between the active region 230 and the active region 231 is 11V, so that the voltage difference between the active region 231 and the tunneling part 224 is greater than a first threshold. Therefore, the read transistor 202 forms the electron tunneling ejection path Path_e to eject the electrons from the charge storage node 200.

In the program mode, the read word line voltage RWL is the low voltage, so that the select transistor 203 is turned off, the program voltage PG and the electronic well voltage NW are both the high voltage, the source line voltage SL is the medium voltage, and the bit line voltage BL is the medium voltage or the low voltage. Therefore, when the bit line voltage BL is the low voltage, the voltage difference between the tunneling part 224 and the active region 231 is sufficient to cause the read transistor 202 to induce the electron tunneling injection for the program operation. In an embodiment, the high voltage is 10V, the medium voltage is 5V, and the low voltage is 0V. In this way, when the bit line voltage BL is 0V, the voltage difference between the active region 230 and the active region 231 is 10V, so that the voltage difference between the active region 231 and the tunneling part 224 is greater than a second threshold. Therefore, the read transistor 202 forms the electron tunneling injection path Path_p to inject the electrons to the charge storage node 200. In contrast, when the bit line voltage BL is 5V, the voltage difference between the active region 230 and the active region 231 is 5V, so that the voltage difference between the active region 231 and the tunneling part 224 is smaller than the second threshold. Therefore, the read transistor 202 does not form the electron tunneling injection path Path_p and the electron tunneling ejection path Path_e.

In the read mode, the read word line voltage RWL is a power voltage, so that the select transistor 203 is turned on. The program voltage PG and the electronic well voltage NW are both the specific bias voltage, the source line voltage SL is the low voltage, and the bit line voltage BL is a read voltage. The read current IR2 depends on the voltage of the read gate part 226 (i.e. the charge storage node 200), and flows from the select transistor 203 to the read transistor 202 along the read path. Therefore, the logical status of the charge storage node 200 may be determined according to the current value of the read current IR2.

It should be noted that, the voltage values of the above-mentioned high voltage, medium voltage, read voltage, low voltage and negative voltage are only embodiments of the present invention, and those skilled in the art may make appropriate adjustments according to the system requirements.

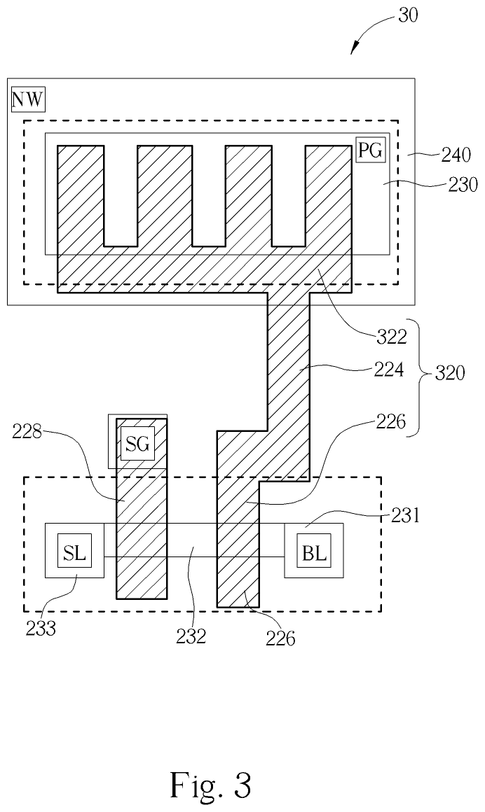

In another embodiment, please refer to FIG. 3. FIG. 3 is a top view of a circuit layout of a non-volatile memory cell 30 according to an embodiment of the present invention. The structure of the non-volatile memory cell 30 is similar to the structure of the non-volatile memory cell 20, so the same symbols are used for the same components. The difference from the non-volatile memory cell 20 is that a coupling gate part 322 of the non-volatile memory cell 30 is in a layout of finger type. In this way, a channel decoupling effect between the first conductive region 230 and the coupling gate part 322 may be minimized, so that the program, erase, and read operations may be performed normally.

In summary, the non-volatile memory cell of the present invention includes three transistors or devices. The PMOS is utilized as the coupling transistor and disposed on the N well, so that the negative voltage and the high voltage may be applied to the first conductive region. Therefore, the read transistor 202 may form the electron tunneling ejection path and the electron tunneling injection path to perform the erase operation and the program operation for the non-volatile memory cell. Compared with the prior art, the non-volatile memory cell of the present invention may include only three transistors or devices to realize the program, erase, read operations. In addition, the non-volatile memory cell of the present invention may include only one N electronic well, which may simplify the steps of semiconductor manufacturing process and reduce the layout area of the non-volatile memory cell.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A non-volatile memory cell, comprising:
a tunneling part;
a coupling transistor, comprising a coupling gate part, a first conductive region and a second conductive region, wherein the coupling gate part is coupled to the tunneling part, and disposed in the first conductive region;
a read transistor, comprising a read gate part coupled to the tunneling part, for forming an electron tunneling ejection path in an erase mode, and forming an electron tunneling injection path in a program mode; and
a select transistor, connected in series with the read transistor, for forming a read path with the read transistor in a read mode.

2. The non-volatile memory cell of claim 1, wherein the first conductive region includes a first active region, the second conductive region includes an electronic well, and the first active region is disposed in the electronic well.

3. The non-volatile memory cell of claim 2, wherein the first active region surrounds the coupling gate part.

4. The non-volatile memory cell of claim 1, wherein the electron tunneling ejection path is the same as the electron tunneling injection path.

5. The non-volatile memory cell of claim 1, wherein the read path is different from the electron tunneling ejection path and the electron tunneling injection path.

6. The non-volatile memory cell of claim 1, wherein a second active region is disposed between the read gate part of the read transistor and a select gate part of the select transistor, and the read transistor is connected in series with the select transistor through the second active region.

7. The non-volatile memory cell of claim 6, wherein the first conductive region is used for receiving a first voltage, the second conductive region is used for receiving a second voltage, a first end of the read transistor different from the second active region is used for receiving a read bit line voltage, a second end of the select transistor different from the second active region is used for receiving a source line voltage, and the select gate part is used for receiving a read word line voltage.

8. The non-volatile memory cell of claim 7, wherein when the non-volatile memory cell operates in the erase mode, the first voltage is a negative voltage, the second voltage is a low voltage, the read bit line voltage and the source line voltage are both a medium voltage, so that the read transistor induces an electron tunneling ejection.

9. The non-volatile memory cell of claim 7, wherein when the non-volatile memory cell operates in the program mode, the first voltage and the second voltage are both a high voltage, the source line voltage is a medium voltage, the read bit line voltage is a low voltage such that the read transistor induces an electron tunneling injection, or the read bit line voltage is the medium voltage such that the read transistor does not induce the electron tunneling injection.

10. The non-volatile memory cell of claim 7, wherein when the non-volatile memory cell operates in the read mode, the select transistor is turned on, the source line voltage is a low voltage, and the read bit line voltage is a read voltage.

11. The non-volatile memory cell of claim 10, wherein when the non-volatile memory cell operates in the read mode, the first voltage and the second voltage are both a specific bias voltage.

12. The non-volatile memory cell of claim 1, wherein the coupling gate part is arranged as a finger shape or a rectangle.
